(19) United States
(12) Patent Application Publication
(10) Pub. No.: US 2008/0230877 A1
(43) Pub. Date: Sep. 25, 2008

(54) SEMICONDUCTOR PACKAGE HAVING WIRE REDISTRIBUTION LAYER AND METHOD OF FABRICATING THE SAME

(75) Inventors: Hyun-soo Chung, Hwuseong-si (KR); Dong-hyeon Jang, Suwon-si (KR); Son-kwan Hwang, Bucheon-si (KR); Nam-seog Kim, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/050,343

(22) Filed: Mar. 18, 2008

(30) Foreign Application Priority Data
Mar. 19, 2007 (KR) 10-2007-0026806

(51) Int. Cl. H01L 23/495; H01L 21/768

(52) U.S. Cl. 257/666; 438/612; 257/E21.59; 257/E23.037

(57) ABSTRACT

A semiconductor package and a method of fabricating the same. The method includes providing a semiconductor substrate on which a chip pad is formed. A wire redistribution layer connected to the chip pad is formed. An insulating layer which includes an opening exposing a portion of the wire redistribution layer is formed. A metal ink is applied within the opening to thereby form a bonding pad. The applied metal ink within the opening and the insulating layer can be cured simultaneously.

### CROSS-REFERENCE TO RELATED APPLICATIONS

This application claims the benefit of Korean Patent Application No. 10-2007-0026806, filed on Mar. 19, 2007, in the Korean Intellectual Property Office, the disclosure of which is incorporated herein in its entirety by reference.

### BACKGROUND OF THE INVENTION

1. Field of the Invention

The present general inventive concept relates to a semiconductor package and a method of fabricating the same, and more particularly, to a semiconductor package having a wire redistribution layer and a method of fabricating the same.

2. Description of the Related Art

According to the trend for making a semiconductor package lightweight, thin, short and miniature, a wafer level chip size package—manufactured using a wire redistribution technique has been developed. Such wire retribution technique refers to a technique which forms a wire redistribution layer one end of which is connected to an aluminum pad on a wafer and which connects the other end of the wire redistribution layer to a solder ball or a bonding wire. The other ends of the wire redistribution layer are sparsely positioned as compared to the end connected to the aluminum pad, so that an alignment margin of the solder ball or the bonding wire can be improved.

On the other hand, the wire redistribution layer can include many metal layers. The uppermost metal layer of these metal layers can be formed of gold (Au) in order to improve connectivity to the solder ball or the bonding wire. However, when the entire wire redistribution layer is formed of gold, manufacturing cost can be increased.

### SUMMARY OF THE INVENTION

The present general inventive concept provides a method of fabricating a semiconductor package including a wire redistribution layer, which is capable of lowering process costs, and a semiconductor package manufactured by the method.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept are achieved by providing a method of fabricating a semiconductor package, the method including: providing a semiconductor substrate on which a chip pad is formed; forming a wire redistribution layer connected to the chip pad; forming an insulating layer which includes an opening exposing a portion of the wire redistribution layer; and applying a metal ink within the opening to thereby form a bonding pad.

The foregoing and/or other aspects and utilities of the present general inventive concept may also be achieved by providing a semiconductor package, including: a semiconductor substrate including a chip pad; a wire redistribution layer connected to the chip pad; an insulating layer which includes an opening exposing a portion of the wire redistribution layer; and a bonding pad which is positioned within the opening and is connected to the wire redistribution layer.

The foregoing and/or other aspects and utilities of the present general inventive concept may also be achieved by providing a method of fabricating a semiconductor package, including: forming a wire redistribution layer above a semiconductor substrate; forming an insulating layer which includes an opening exposing a portion of the wire redistribution layer; and applying a metal ink within the opening to form a bonding pad.

The foregoing and/or other aspects and utilities of the present general inventive concept may also be achieved by providing a semiconductor package, including: a wire redistribution layer disposed above a semiconductor substrate; an insulating layer including an opening exposing a portion of the wire redistribution layer; and a bonding pad disposed within the opening and connected to an end of the wire redistribution layer.

The semiconductor package can further include an electrical circuit connected to another end of the redistribution layer.

### BRIEF DESCRIPTION OF THE DRAWINGS

The above and other features and advantages of the present general inventive concept will become more apparent by describing in detail exemplary embodiments thereof with reference to the attached drawings in which:

FIGS. 1A through 1D are sectional views sequentially illustrating a method of fabricating a semiconductor package according to an embodiment of the present general inventive concept; and

FIG. 2 is a sectional view illustrating a method of fabricating a semiconductor package according to another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

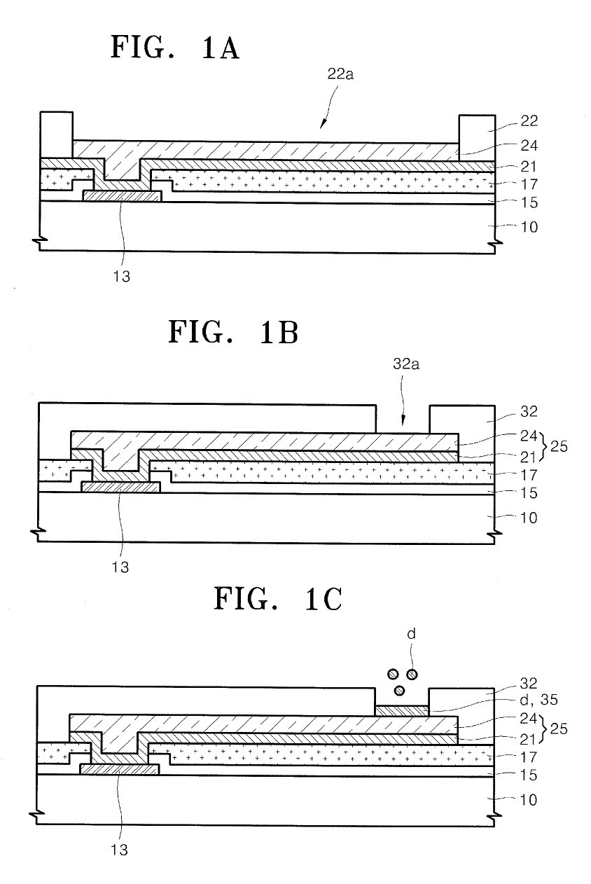

FIGS. 1A through 1D are sectional views sequentially illustrating a method of fabricating a semiconductor package according to an embodiment of the present general inventive concept.

Referring to FIG. 1A, a chip pad 13 which is electrically connected to an electric circuit (not shown) is formed over a semiconductor substrate 10 on which the electric circuit is formed. The chip pad 13 may be an aluminum (Al) layer or a copper (Cu) layer. The semiconductor substrate 10 includes a plurality of unit chips which are separated from each other by a scribe lane, and the chip pad 13 is formed over each unit chip.

A passivation layer 15 is formed on the chip pad 13. A first interlayer insulating layer 17 can be formed on the passivation layer 15. The passivation layer 15 may be a silicon nitride layer, a silicon oxide layer, a silicon oxynitride layer or a combination thereof. The first interlayer insulating layer 17 may be a photoresist layer, such as a polyimide (PI) layer, a polybenzooxazole (PBO) layer or a benzocyclobutene (BCB) layer. An opening which exposes the passivation layer 15 within the first interlayer insulating layer 17 is formed by exposing and developing the first interlayer insulating layer 17. Subsequently, the first interlayer insulating layer 17 is cured. A contact hole exposes the chip pad 13 within the first interlayer insulating layer 17 and the passivation layer 15 and is formed by etching the exposed passivation layer 15 using the cured first interlayer insulating layer 17 as a mask.

A seed layer 21 is formed on the chip pad 13 which is exposed within the contact hole and the first interlayer insulating layer 17. The seed layer 21 includes a seed adhesion layer (not shown) and a wetting layer (not shown) which are sequentially stacked. The seed adhesion layer is a layer which serves to improve an adhesion between the chip pad 13 and the wetting layer and may be Titanium (Ti), titanium-tungsten (TiW), titanium nitride (TiN), chrome (Cr), aluminum (Al) or their alloy layer. In addition, the wetting layer is a layer which serves as a seed to a metal layer which is formed in a subsequent process and may be copper (Cu), nickel (Ni), nickel vanadium (NiV) or their alloy layer. The seed adhesion layer can be a titanium (Ti) layer, and the wetting layer can be a copper (Cu) layer in which a wettability is good and which is low in cost. The seed adhesion layer and the wetting layer can be successively formed using a sputtering method.

A mask layer 22 is formed on the seed layer 21. The mask layer 22 includes an opening 22a which exposes a portion of the seed layer 21. The opening 22a is overlapped with the chip pad 13. The mask layer 22 may be a photoresist layer.

The redistribution metal layer 24 is formed on the seed layer 21 which is exposed within the opening 22a. The redistribution metal layer 24 can be formed using a sputtering method and a plating method. However, preferably, the redistribution metal layer 24 can be formed using an electroplating method which is one method among plating methods. A current can be supplied via the seed layer 21. The redistribution metal layer 24 may be a copper (Cu) layer, a nickel (Ni) layer, a palladium (Pd) layer, a silver (Ag) layer or their multi layers. The redistribution metal layer 24 can include a first redistribution metal layer (not shown) and a second redistribution metal layer (not shown) which are sequentially stacked, wherein the first redistribution metal layer may be a copper layer and the second redistribution metal layer may be a nickel layer. The copper layer and the nickel layer are low cost, and they have good adhesion and durability.

Referring to FIG. 1B, after removing the mask pattern 22 to expose the seed layer 21, the exposed seed layer 21 is etched using the redistribution metal layer 24 as a mask. As a result, a wire redistribution layer 25 which includes the sequentially stacked seed layer 21 and the redistribution metal layer 24 is formed.

One end of the wire redistribution layer 25 is connected to the chip pad 13. A second interlayer insulating layer 32 is formed on a substrate which includes the wire redistribution layer 25. The second interlayer insulating layer 32 may be a photoresist layer, such as a polyimide layer, a polybenzooxazole layer or a benzocyclobutene layer. An opening 32a which exposes an other end region of the wire redistribution layer 25 within the second interlayer insulating layer 32 is formed by selectively exposing and developing a portion of a region of the second interlayer insulating layer 32.

Referring to FIG. 1C, a metal ink d is applied on the wire redistribution layer 25 which is exposed within the opening 32a. Applying the metal ink can be performed using a jetting method, a dropping method, a spraying method or a printing method. The metal ink d can comprise gold (Au), silver (Ag), copper (Cu) or nickel (Ni). Preferably, but not necessarily, the metal ink d is a gold ink.

In a subsequent process, the applied metal ink d is cured. In this process, a solvent which is contained in the metal ink d is volatilized and metal particles are co-agglomerated so that a bonding pad 35 is formed. The bonding pad 35 is formed at a portion, and not the whole region, of the wire redistribution layer 25. Therefore, a material to form the bonding pad 35 is saved. In addition, a thickness of the wire redistribution layer 25 can be reduced as compared with a case where the bonding pad 35 is formed on the whole surface of the redistribution metal layer 24.

The applied metal ink d and the second interlayer insulating layer 32 can be cured, simultaneously. As a result, an adhesive strength of an interface between the bonding pad 35 and the second interlayer insulating layer 32 can be improved as well as the curing process for the second interlayer insulating layer 32 and the curing process for the applied metal ink d are performed at a same time, so that the process can be simplified.

Referring to FIG. 1D, the semiconductor substrate 10 is sawed along a scribe line, so that the unit chips are separated from each other. Thereafter, a connecting terminal 43 is connected to the bonding pad 35. The connecting terminal 43 may be a bump, a ball, or a bonding wire. The connecting terminal 43 can comprise gold (Au), silver (Ag), copper (Cu) or nickel (Ni). When considering connecting characteristics, the connecting terminal 43 and the bonding pad 35 are preferably made of the same material. Preferably, a material of the connecting terminal 43 is a gold alloy.

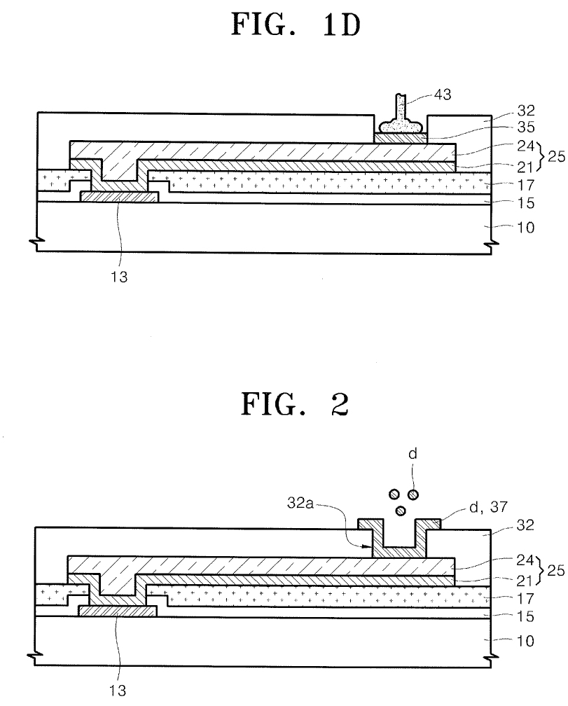

FIG. 2 is sectional view illustrating a method of fabricating a semiconductor package according to another embodiment of the present general inventive concept. The method of fabricating the semiconductor device according to the present embodiment is similar to the method of fabricating the semiconductor device as described with reference to FIGS. 1A through 1D except for those as described below.

Referring to FIG. 2, when applying a metal ink d on a wire redistribution layer 25 which is exposed within an opening 32a formed within a second interlayer insulating layer 32, the metal ink d is applied to a top surface of the wire redistribution layer 25 which is exposed within the opening 32a and a top surface of an interlayer insulating layer 32 adjacent to the opening 32a. Thereafter, the applied metal ink d is cured so that a bonding pad 37 is formed. The bonding pad 37, positioned within the opening 32a, is connected to the wire redistribution layer 25, and is extended onto the upper surface of the interlayer insulating layer 32 adjacent to the opening 32a. Thus, an area of the bonding pad 37 is increased, so that in the subsequent process, a formation margin of the connecting terminal (43 in FIG. 1D) which is formed on the bonding pad 37 can be improved. However, in applying the metal ink d, an applying region of the metal ink d should be controlled such that the bonding pad 37 is sufficiently spaced apart from other bonding pads adjacent to the subject bonding pad 37.

According to embodiments of the present general inventive concept as described above, a bonding pad can be formed on a portion of a region, and not on the whole region, of a wire redistribution layer. Therefore, the material to form the bonding pad can be saved, and the thickness of the wire redistribution layer can be reduced. In addition, the interface adhesive between the bonding pad and the interlayer insulating layer can be improved by curing the applied metal ink to form the bonding pad and the interlayer insulating layer, simultaneously.

While the present general inventive concept has been particularly shown and described with reference to exemplary embodiments thereof, it will be understood by those of ordinary skill in the art that various changes in form and details may be made therein without departing from the spirit and scope of the general inventive concept as defined by the following claims.

What is claimed is:

1. A method of fabricating a semiconductor package, comprising:
providing a semiconductor substrate on which a chip pad is formed;
forming a wire redistribution layer connected to the chip pad;
forming an insulating layer which includes an opening exposing a portion of the wire redistribution layer; and
applying a metal ink within the opening to thereby form a bonding pad.

2. The method of claim 1, further comprising:
simultaneously curing the metal ink which is applied within the opening and the insulating layer.

3. The method of claim 1, wherein the applying the metal ink is performed using a jetting method, a dropping method, a spraying method or a printing method.

4. The method of claim 1, wherein the metal ink comprises gold (Au), silver (Ag), copper (Cu) or nickel (Ni).

5. The method of claim 1, wherein the metal ink is also applied on the insulating layer adjacent to the opening.

6. The method of claim 1, wherein the insulating layer is a polyimide (PI) layer, a polybenzooxazole (PBO) layer or a benzocyclobutene (BCB) layer.

7. The method of claim 1, wherein the wire redistribution layer comprises a copper (Cu) layer, a nickel (Ni) layer, a palladium (Pd) layer or a silver (Ag) layer.

8. The method of claim 1, further comprising:
forming a passivation layer which includes a contact hole exposing a portion of the chip pad on the chip pad before the forming the wire redistribution layer.

9. A semiconductor package, comprising:
a semiconductor substrate including a chip pad;
a wire redistribution layer connected to the chip pad;
an insulating layer which includes an opening exposing a portion of the wire redistribution layer; and
a bonding pad which is positioned within the opening and is connected to the wire redistribution layer.

10. The semiconductor package of claim 9, wherein the bonding pad comprises gold (Au), silver (Ag), copper (Cu) or nickel (Ni).

11. The semiconductor package of claim 9, wherein the bonding pad is also positioned on the insulating layer adjacent to the opening.

12. The semiconductor package of claim 9, wherein the insulating layer is a polyimide layer, a polybenzooxazole layer or a benzocyclobutene layer.

13. The semiconductor package of claim 9, wherein the wire redistribution layer comprises a copper (Cu) layer, a nickel (Ni) layer, a palladium (Pd) layer or a silver (Ag) layer.

14. The semiconductor package of claim 9, wherein a passivation layer which includes a contact hole exposing a portion of the chip pad is positioned on the chip pad, and the wire redistribution layer is connected to the chip pad exposed within the contact hole.

15. A method of fabricating a semiconductor package, comprising:
forming a wire redistribution layer above a semiconductor substrate;
forming an insulating layer which includes an opening exposing a portion of the wire redistribution layer; and
applying a metal ink within the opening to form a bonding pad.

16. The method of claim 15, further comprising:
simultaneously curing the metal ink which is applied within the opening and the insulating layer.

17. The method of claim 15, wherein the forming a wire redistribution layer comprises forming a wire redistribution layer such that one end is connected to an electrical circuit.

18. A semiconductor package, comprising:
a wire redistribution layer disposed above a semiconductor substrate;
an insulating layer including an opening exposing a portion of the wire redistribution layer; and
a bonding pad disposed within the opening and connected to an end of the wire redistribution layer.

19. The semiconductor package of claim 18, further comprising:
an electrical circuit connected to another end of the redistribution layer.

20. The semiconductor package of claim 18, wherein the bonding pad is also disposed on a portion of the insulating layer.

21. The semiconductor package of claim 19, further comprising:
a connecting terminal connected to an upper portion of the bonding pad to supply electricity to the electrical circuit.
